(19) United States
(12) Patent Application Publication
(10) Pub. No.: US 2026/0114316 A1
(43) Pub. Date: Apr. 23, 2026

(54) HIGH BANDWIDTH MEMORY AND METHOD FOR MANUFACTURING THE SAME

(71) Applicant: Samsung Electronics Co., Ltd., Suwon-si (KR)

(72) Inventors: SUNYOUNG KIM, Suwon-si (KR); YEONSEOP YU, Suwon-si (KR); JONG-HYUK KO, Suwon-si (KR); YUNGCHEOL KONG, Suwon-si (KR)

(21) Appl. No.: 19/337,336

(22) Filed: Sep. 23, 2025

(30) Foreign Application Priority Data
Oct. 17, 2024 (KR) 10-2024-0142472

(51) Int. Cl. H01L 23/31; H01L 21/56; H01L 23/00; H01L 23/29; H01L 25/18; H10B 80/00; H10D 80/30

(52) U.S. Cl. CPC H10W 74/121; H10B 80/00; H10D 80/30; H10W 74/01; H10W 90/00; H10W 72/07232; H10W 74/47; H10W 90/28; H10W 90/297; H10W 90/722

(57) ABSTRACT

A semiconductor package according to some embodiments includes: a first semiconductor die; a plurality of first connection members on the first semiconductor die; a second semiconductor die on the plurality of first connection members; an insulating member spaced apart from the first semiconductor die between the first semiconductor die and the second semiconductor die and that covers at least a portion of a lower surface of the second semiconductor die and the plurality of first connection members; and a molding material that covers at least a portion of the second semiconductor die and is between the first semiconductor die and the second semiconductor die.

### CROSS-REFERENCE TO RELATED APPLICATION

This application claims priority to and the benefit of Korean Patent Application No. 10-2024-0142472, filed at the Korean Intellectual Property Office on Oct. 17, 2024, the entire contents of which are incorporated herein by reference.

### FIELD

The present disclosure relates to a high bandwidth memory and a method for manufacturing the same.

### BACKGROUND

In line with a demand for miniaturization and weight reduction for an electronic device, the semiconductor industry is pursuing miniaturization, weight reduction, and thinning of a semiconductor package mounted on the electronic device while simultaneously pursuing higher speed, multi-functionality, and large capacity of the semiconductor package. Therefore, a need for a packaging technology capable of storing more data and transferring faster data is increasing. A high bandwidth memory (HBM) formed by stacking a plurality of individual memory dies has recently been developed and used as the packaging technology.

To manufacture the high bandwidth memory (HBM), the memory dies may be bonded by performing thermal compression (TC) bonding on microbumps and an underfill member disposed between the memory die and a memory. However, during the thermal compression bonding, the underfill member may be excessively exposed so that a fillet is formed or an unfilled area occurs in some areas. The fillet may form an irregular boundary surface with a molding material covering the memory dies, and for example, the irregular boundary surface due to the fillet may cause a crack to occur, and the irregular boundary surface due to the fillet may make the high bandwidth memory (HBM) structurally unstable. This may cause a reliability problem of the high bandwidth memory (HBM).

### SUMMARY

A high bandwidth memory and a method for manufacturing the same according to some embodiments of the present disclosure are intended to prevent occurrence of an unfilled area between semiconductor dies.

A high bandwidth memory and a method for manufacturing the same according to some embodiments of the present disclosure are intended to prevent fillet formation between semiconductor dies.

A semiconductor package according to some embodiments includes: a first semiconductor die; a plurality of first connection members on the first semiconductor die; a second semiconductor die on the plurality of first connection members; an insulating member spaced apart from the first semiconductor die between the first semiconductor die and the second semiconductor die and that covers at least a portion of a lower surface of the second semiconductor die and the plurality of first connection members; and a molding material that covers at least a portion of the second semiconductor die and is between the first semiconductor die and the second semiconductor die.

A high bandwidth memory according to some embodiments includes: a buffer die; a plurality of memory dies stacked in a vertical direction on the buffer die; a plurality of first connection members between the buffer die and the memory die adjacent the buffer die and between memory dies adjacent each other among the plurality of memory dies; a plurality of insulating members between the buffer die and the memory die adjacent the buffer die and between memory dies adjacent each other among the plurality of memory dies and surrounding the plurality of first connection members; and a molding material on the buffer die and covering the plurality of insulating members, between the buffer die and the memory die adjacent the buffer die, between adjacent memory dies among the plurality of memory dies, and at least partially covering the plurality of memory dies.

A method for manufacturing a semiconductor package according to some embodiments includes: forming a plurality of first bonding pads on a first semiconductor die; forming a plurality of first connection members on a lower surface of a second semiconductor die; attaching an insulating member on the lower surface of the second semiconductor die and on the plurality of first connection members; bonding the second semiconductor die on the first semiconductor die; and molding the first semiconductor die and the second semiconductor die on the first semiconductor die. The insulating member has a thickness less than heights of the plurality of first connection members.

### BRIEF DESCRIPTION OF THE DRAWINGS

FIG. 1 IS A VIEW SHOWING A MEMORY DIE AND A BUFFER DIE ACCORDING TO SOME embodiments.

FIGS. 2 to 5 are cross-sectional views for describing a method for manufacturing the memory die and the buffer die according to FIG. 1.

FIG. 6 is a view showing a memory die and a buffer die according to some other embodiments.

FIGS. 7 to 10 are cross-sectional views for describing a method for manufacturing the memory die and the buffer die according to FIG. 6.

FIG. 11 is a cross-sectional view illustrating a high bandwidth memory according to some embodiments.

FIG. 12 is a cross-sectional view illustrating a high bandwidth memory according to some other embodiments.

### DETAILED DESCRIPTION

Example embodiments of the present disclosure will be described more fully hereinafter with reference to the accompanying drawings so that those skilled in the art could easily implement the example embodiments. The present disclosure may be modified in various ways, all without departing from the spirit or scope of the present disclosure.

In order to clearly describe the present disclosure, parts or portions that are irrelevant to the description may be omitted, and identical or similar constituent elements throughout the specification are denoted by the same reference numerals.

In the drawings, each element's size and thickness may be arbitrarily illustrated for ease of description, but the present disclosure is not necessarily limited to those illustrated in the drawings.

Throughout the specification, when a part is “connected” to another part, it includes not only a case where the part is “directly connected” but also a case where the part is “indirectly connected” with another part in between. Unless explicitly stated to the contrary, the word “comprise” and variations such as “comprises” and “comprising” should be understood to imply the inclusion of stated elements but not the exclusion of any other elements.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” may mean disposed on or below a referenced part, and does not necessarily mean disposed on the upper side of the referenced part based on a gravitational direction.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

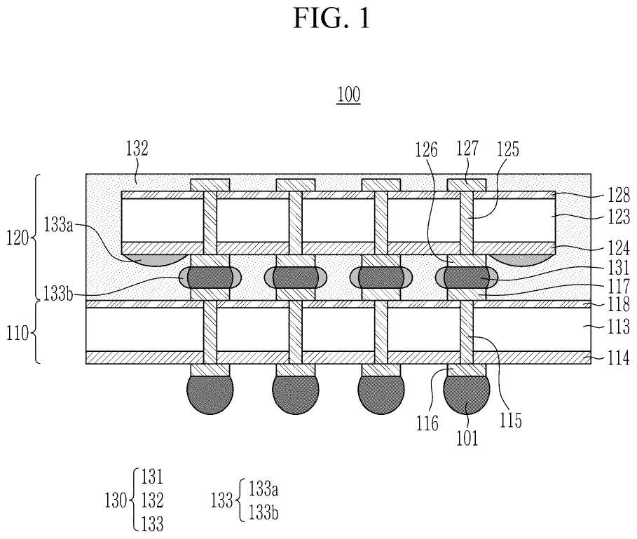

FIG. 1 is a view showing a memory die and a buffer die according to some embodiments.

As shown in FIG. 1, a semiconductor package 100 may include a buffer die (or a base logic die) 110 and a memory die 120.

The buffer die 110 may be disposed below or at a lowermost portion of the semiconductor package 100. In some embodiments, the buffer die 110 may be disposed between the semiconductor package 100 and an external device.

When data is exchanged between devices with different data processing speeds, different processing units, and different usage times, data loss may occur due to a difference in data processing speeds, a difference in processing units, and a difference in usage times between the devices. To prevent the data loss, the buffer die 110 may temporarily store information when data is exchanged between the semiconductor package 100 and the external device. If the semiconductor package 100 receives data from the external device or the semiconductor package 100 transmits data to the external device, the buffer die 110 may sequentially pass the data after aligning an order of the data.

The buffer die 110 may include a buffer die base or buffer die base substrate 113, a first front side structure (or a first front surface structure) 114, a plurality of first through-hole silicon vias 115, a plurality of first connection pads 116, a plurality of first bonding pads 117, and a first back side structure (or a first back surface structure) 118.

The buffer die base 113 may include an active side (e.g., a front side) and a back side that is an opposite side of the active side. The buffer die base 113 may be a die formed from a wafer. In some embodiments, the buffer die base 113 may include silicon or another semiconductor material.

The first front side structure 114 may be disposed on a lower surface of the buffer die base 113 (e.g., the active side (or an active surface) of the buffer die base 113). The first front side structure 114 may include an active layer and a wiring layer. The active layer may be disposed on the active side of the buffer die base 113. The active layer may include an integrated circuit structure having integrated circuit areas. In some embodiments, the integrated circuit structure may include at least one of an active device and a passive device. In some embodiments, the integrated circuit structure may include a gate structure, a source area, and a drain area. In some embodiments, the integrated circuit structure may include at least one of a transistor, a diode, a capacitor, an inductor, and a resistor. The wiring layer may be disposed on the active layer. The wiring layer may include a wiring line for a signal, a wiring line for electric power, a contact plug, and an inter-metal dielectric (IMD).

The plurality of first through-hole silicon vias 115 may be disposed within the buffer die base 113. Each of the plurality of first through-hole silicon vias 115 may penetrate the buffer die base 113. Each of the plurality of first through-hole silicon vias 115 may be disposed between each of the plurality of first connection pads 116 on the first front side structure 114 and each of the plurality of first bonding pads 117. Each of the plurality of first through-hole silicon vias 115 may be electrically connected to each of the plurality of first bonding pads 117 corresponding to the active layer or the wiring layer of each of the first front side structure 114. In some embodiments, each of the plurality of first through-hole silicon vias 115 may include at least one of tungsten, aluminum, copper, and an alloy thereof.

Each of the plurality of first connection pads 116 may be disposed between the wiring layer of the first front side structure 114 and each of a plurality of external connection members 101. Each of the plurality of first connection pads 116 may electrically connect the wiring layer of the first front side structure 114 to each of the plurality of external connection members 101. In some embodiments, each of the plurality of first connection pads 116 may include at least one of copper, aluminum, tungsten, nickel, gold, tin, titanium, and an alloy thereof.

The plurality of first bonding pads 117 may be disposed on an upper surface of the buffer die base 113 (e.g., the back side (or a back surface) of the buffer die base 113). Each of the plurality of first bonding pads 117 may be disposed between each of the plurality of first through-hole silicon vias 115 and each of a plurality of first connection members 131. Each of the plurality of first bonding pads 117 may electrically connect each of the plurality of first through-hole silicon vias 115 to a first connection member among the plurality of first connection members 131 corresponding to each of the plurality of first through-hole silicon vias 115. In some embodiments, each of the plurality of first bonding pads 117 may include at least one of copper, aluminum, tungsten, nickel, gold, tin, titanium, and an alloy thereof.

The first back side structure 118 may be disposed on the upper surface of the buffer die base 113 (e.g., an inactive side (or an inactive surface) of the buffer die base 113). In some embodiments, a thickness of the first back side structure 118 may be less or smaller than a thickness of the first front side structure 114.

The plurality of external connection members 101 may be disposed between the plurality of first connection pads 116 and the external device. Each of the plurality of external connection members 101 may electrically connect each of the plurality of first connection pads 116 to the external device. In some embodiments, each of the plurality of external connection members 101 may include a microbump or a solder ball. In some embodiments, each of the plurality of external connection members 101 may include at least one of tin, silver, lead, nickel, copper, and an alloy thereof.

The memory die 120 may include a memory die base or memory die base substrate 123, a second front side structure (or a second front surface structure) 124, a plurality of second through-hole silicon vias 125, a plurality of second connection pads 126, a plurality of second bonding pads 127, and a second back side structure (or a second back surface structure) 128.

The memory die base 123 may include an active side (e.g., a front side) and a back side that is an opposite side of the active side. The memory die base 123 may be disposed so that the active side faces the buffer die 110. The memory die base 123 may be a die formed from a wafer. In some embodiments, the memory die base 123 may include silicon or another semiconductor material.

The second front side structure 124 may be disposed on a lower surface (e.g., the active side) of the memory die base 123. The second front side structure 124 may include an active layer and a wiring layer. The active layer may be disposed on the active side of the memory die base 123. The active layer may include an integrated circuit structure having integrated circuit areas. In some embodiments, the integrated circuit structure may include at least one of an active device and a passive device. In some embodiments, the integrated circuit structure may include a gate structure, a source area, and a drain area. In some embodiments, the integrated circuit structure may include at least one of a transistor, a diode, a capacitor, an inductor, and a resistor. The wiring layer may be disposed on the active layer. The wiring layer may include a wiring line for a signal, a wiring line for electric power, a contact plug, and an inter-metal dielectric (IMD).

The plurality of second through-hole silicon vias 125 may be disposed within the memory die base 123. Each of the plurality of second through-hole silicon vias 125 may penetrate the memory die base 123. Each of the plurality of second through-hole silicon vias 125 may be disposed between each of the plurality of second connection pads 126 on the second front side structure 124 and each of the plurality of second bonding pads 127. Each of the second through-hole silicon vias 125 may electrically connect the active layer or the wiring layer of the second front side structure 124 to a second bonding pad among the plurality of second bonding pads 127 corresponding to the active layer or the wiring layer of the second front side structure 124. In some embodiments, each of the plurality of second through-hole silicon vias 125 may include at least one of tungsten, aluminum, copper, and an alloy thereof.

The plurality of second connection pads 126 may be disposed between the wiring layer of the second front side structure 124 and the plurality of first connection members 131. Each of the plurality of second connection pads 126 may electrically connect the wiring layer of the second front side structure 124 to a first connection member among the plurality of first connection members 131 corresponding to the wiring layer of the second front side structure 124. In some embodiments, each of the plurality of second connection pads 126 may include at least one of copper, aluminum, tungsten, nickel, gold, tin, titanium, and an alloy thereof.

The plurality of second bonding pads 127 may be disposed on an upper surface (e.g., a back side (or a back surface)) of the memory die base 123. The plurality of second bonding pads 127 may be disposed on a second through-hole via among the plurality of second through-hole silicon vias 125 corresponding to the second bonding pad 127 and on the second back side structure 128. In some embodiments, each of the plurality of second bonding pads 127 may include at least one of copper, aluminum, tungsten, nickel, gold, tin, titanium, and an alloy thereof.

The second back side structure 128 may be disposed on an upper surface of the memory die base 123 (e.g., an inactive side (or an inactive surface) of the memory die base 123). In some embodiments, a thickness of the second back side structure 128 may be less or smaller than a thickness of the second front side structure 124.

An interconnection structure 130 may be disposed between the memory die 120 and the buffer die 110. Additionally, the interconnection structure 130 may be disposed to surround the memory die 120. The interconnection structure 130 may include the plurality of first connection members 131, a molding material 132, and an insulating member 133.

Each of the plurality of first connection members 131 may be disposed between each of the plurality of first bonding pads 117 and each of the plurality of second connection pads 126. Each of the plurality of first connection members 131 may electrically connect each of the plurality of second connection pads 126 to a first bonding pad among the plurality of first bonding pads 117 corresponding to each of the plurality of second connection pads 126. In some embodiments, each of the plurality of first connection members 131 may include a microbump. In some embodiments, each of the plurality of first connection members 131 may include at least one of tin, silver, lead, nickel, copper, and an alloy thereof.

In some embodiments, each of the plurality of first connection members 131 may have a height or thickness of 6 μm to 8 μm. For example, each of the plurality of first connection members 131 may have a height of 7.6 μm.

The insulating member 133 may be disposed between the buffer die 110 and the memory die 120 adjacent to the buffer die 110. The insulating member 133 may be spaced apart from the buffer die 110. The insulating member 133 may be on, cover, or surround at least a portion of a lower surface of the memory die 120 and the plurality of first connection members 131.

In some embodiments, the insulating member 133 may be a polymer tape including an insulating material for uniform adhesion between the buffer die 110 and the memory die 120, bonding of the plurality of first connection members 131 of fine sizes, electrical reliability, structural reliability, and the like. For example, the insulating member 133 may include a non-conductive film (NCF). The insulating member 133 may include at least one of a thermosetting resin, a hardener (or a curing agent), a catalyst, a flux, a thermoplastic resin, and an inorganic filler.

The thermosetting resin may be selected from materials having a thermal or mechanical characteristic suitable as an underfill film. In some embodiments, the thermosetting resin may include an epoxy resin. In some embodiments, the epoxy resin may include at least one of a bisphenol-type epoxy resin and a novolac-type epoxy resin.

The hardener may be added to the thermosetting resin to harden (or cure) the thermosetting resin. The hardener may be added to adjust a degree of hardening of the thermosetting resin. A mechanical characteristic of the insulating member 133 may be adjusted by adding the hardener to the thermosetting resin. In some embodiments, the hardener may include at least one of an amine-based compound, an acid anhydride-based compound, an amide-based compound, an imidazole-based compound, and a phenol-based compound.

The catalyst may be added to the thermosetting resin to adjust a hardening speed of the thermosetting resin. The hardening speed of the thermosetting resin may be adjusted according to a content of the catalyst, or may be adjusted using the catalyst that slows the hardening speed. In some embodiments, the catalyst may include at least one of a phosphorus-based compound, a boron-based compound, a phosphorus-boron-based compound, and an imidazole-based compound.

The flux may improve wetting of the plurality of first connection members 131 for the plurality of first bonding pads 117 and the plurality of second connection pads 126. In some embodiments, the flux may include at least one of carboxylic acid, phenol, and amine.

The thermoplastic resin may increase fluidity of the insulating member 133 at a temperature at which thermal compression (TC) bonding is performed, so that the plurality of first connection members 131 are well bonded to the plurality of first bonding pads 117. The thermoplastic resin may reduce a thermal stress and a mechanical stress between the buffer die 110 and the memory die 120. In some embodiments, the thermoplastic resin may include at least one of a polyimide-based resin, a polyether imide-based resin, a polyether sulfone-based resin, a polyether ketone-based resin, a polyolefin-based resin, a polyvinyl chloride-based resin, a phenoxy-based resin, a butadiene rubber, a styrene-butadiene rubber, a modified butadiene rubber, a reactive butadiene acrylonitrile copolymer rubber, and an acrylate-based resin.

The inorganic filler may be added as a filler material within the insulating member 133. The inorganic filler may suppress a flow of the insulating member 133 to improve bonding reliability of the plurality of first connection members 131 for the plurality of first bonding pads 117. In some embodiments, the inorganic filler may include silica.

The insulating member 133 may include a first insulating member 133a and a second insulating member 133b. The first insulating member 133a may be disposed on a lower surface of the memory die 120 (e.g., at least a portion of an area of the second front side structure 124). The first insulating member 133a may insulate between the memory die 120 and the buffer die 110.

The first insulating member 133a may extend in a direction perpendicular to the memory die base 123 from the second front side structure 124 toward the buffer die 110. The second insulating member 133b may surround each of the plurality of first connection members 131. The second insulating member 133b may surround a side surface of each of the plurality of first connection members 131 except for a surface on which each of the plurality of first connection members 131 is in contact with the second connection pad and the first bonding pad corresponding to each of the plurality of first connection members. The second insulating member 133b may be disposed between the plurality of first connection members 131 to prevent an electrical short-circuit from occurring between the plurality of first connection members 131.

The second insulating member 133b may extend from the plurality of first connection members 131 in a direction parallel to the memory die base 123 or the buffer die base 113. For example, the second insulating member 133b may extend (e.g., outwardly) from a center of each of the plurality of first connection members 131 in the direction parallel to the buffer die base 113.

A thickness of each of the first insulating member 133a and the second insulating member 133b may be less than an interval or spacing between the buffer die 110 and the memory die 120. In some embodiments, the thickness of each of the first insulating member 133a and the second insulating member 133b may be less than heights or thicknesses of the plurality of first connection members 131. The second insulating member 133b may be disposed to be separated or spaced apart from the first insulating member 133a.

The molding material 132 may be or cover between the buffer die 110 and the memory die 120 on the buffer die 110. The molding material 132 may cover side and upper surfaces of the memory die 120. The molding material 132 may serve to protect and insulate the buffer die 110, the memory die 120, and the plurality of first connection members 131.

In some embodiments, the molding material 132 may include an epoxy molding compound (EMC). In some embodiments, the molding material 132 may include at least one of a thermosetting resin, a hardener (or a curing agent), a flame retardant, a catalyst, a release agent, a modifying agent, a colorant, and an inorganic filler. In some embodiments, the inorganic filler of the molding material 132 may include silica.

The molding material 132 may be in or fill an area that is not filled by the first insulating member 133a and the second insulating member 133b between the memory die 120 and the buffer die 110. The first insulating member 133a and the second insulating member 133b may be in contact with the molding material 132.

For example, each of the plurality of first connection members 131 may have a height of 7.6 μm. For example, a thickness of each of the first insulating member 133a and the second insulating member 133b may be 2 μm to 3.8 μm. In some embodiments, a thickness of the molding material 132 may be greater than thicknesses of the first insulating member 133a and the second insulating member 133b between the memory die 120 and the buffer die 110.

Because the thickness of each of the first insulating member 133a and the second insulating member 133b is small, the first insulating member 133a and the second insulating member 133b may not overflow in a peripheral direction even if the memory die 120 and the base die 110 are bonded. Accordingly, a fillet area formed by the insulating member 133 may be reduced.

However, the present disclosure is not limited thereto, and the thickness of each of the first insulating member 133a and the second insulating member 133b may be a thickness capable of preventing a sweep phenomenon in which the plurality of first connection members 131 flow out or move out of their positions due to thermal compression bonding to escape an electrical path or a short phenomenon in which each of the plurality of first connection members 131 is connected to another first connection member adjacent to each of the plurality of first connection members 131 so that a short circuit occurs.

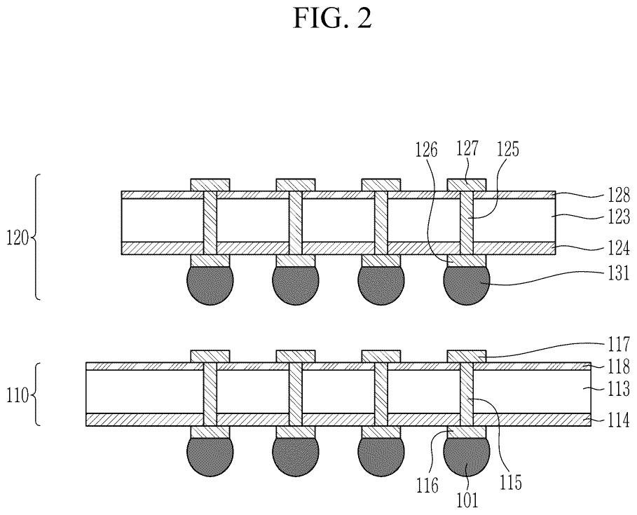

FIGS. 2 to 5 are cross-sectional views for describing a method for manufacturing the memory die and the buffer die according to FIG. 1.

FIG. 2 is a cross-sectional view illustrating a step of aligning the memory die 120 on the buffer die 110.

Referring to FIG. 2, the memory die 120 may be aligned on the buffer die 110. The plurality of first bonding pads 117 may be attached to an upper surface of the buffer die 110 (e.g., on the first back side structure 118). The plurality of second connection pads 126 and the plurality of first connection members 131 may be attached to a lower surface of the memory die 120 (e.g., above or on the second front side structure 124).

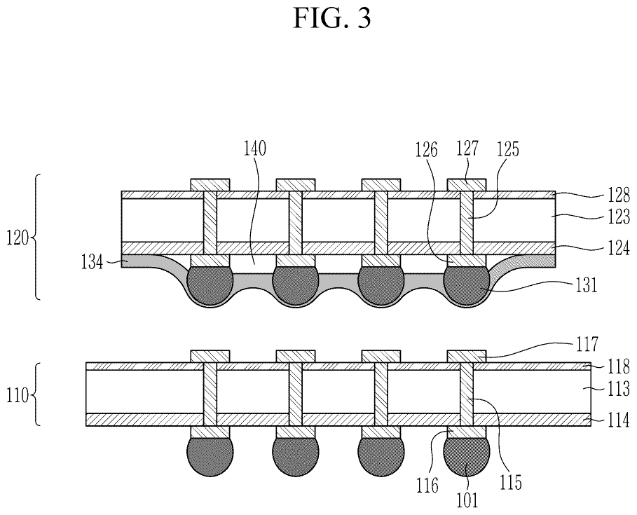

FIG. 3 is a view showing a step of attaching an insulating member 134 on the lower surface of the memory die 120.

Referring to FIG. 3, the insulating member 134 may be attached to the lower surface of the memory die 120 and the plurality of first connection members 131. In some embodiments, a thickness of the insulating member 134 may be less than heights or thicknesses of the plurality of first connection members 131. The plurality of second connection pads 126 and the plurality of first connection members 131 may be covered by the insulating member 134 on the lower surface of the memory die 120.

A thickness of the insulating member 134 may be less than an interval or spacing between the memory die 120 and the base die 110. In some embodiments, the thickness of the insulating member 134 may be 2 μm to 3.8 μm.

If the thickness of the insulating member 134 is small compared with the heights of the plurality of first connection members 131, an unfilled area 140 in which the insulating member 134 is not filled may exist between the plurality of second connection pads 126. As a result, the memory die 120 and the buffer die 110 may not be evenly bonded, or a void may occur between the memory die 120 and the buffer die 110.

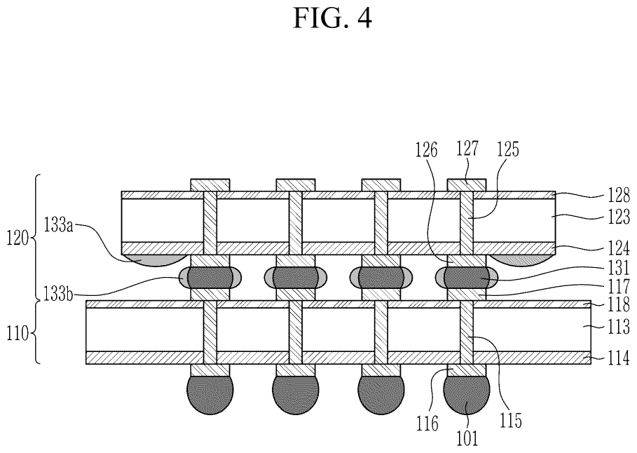

FIG. 4 is a view showing a step of bonding the memory die 120 on the buffer die 110.

Referring to FIG. 4, the memory die 120 may be bonded on the buffer die 110. The memory die 120 may be bonded on the buffer die 110 by a thermal compression process. The plurality of first connection members 131 and an insulating member on the plurality of first connection members 131 may be bonded to a first bonding pad among the plurality of first bonding pads 117 corresponding to the plurality of first connection members 131 and the insulating member on the plurality of first connection members 131 by the thermal compression process.

The insulating member 134 may be in a gel state before the thermal compression process is performed, may change from the gel state to a liquid state by applying heat during the thermal compression process, and may finally be in a hardened state (or a cured state). During the thermal compression process, the insulating member 134 in the liquid state may be separated into the first insulating member 133a attached to the second front side structure 124 of the memory die 120 by the unfilled area 140 and the second insulating member 133b surrounding each of the plurality of first connection members 131. After the thermal compression process is completed, the first insulating member 133a and the second insulating member 133b may be in a hardened state (or a cured state).

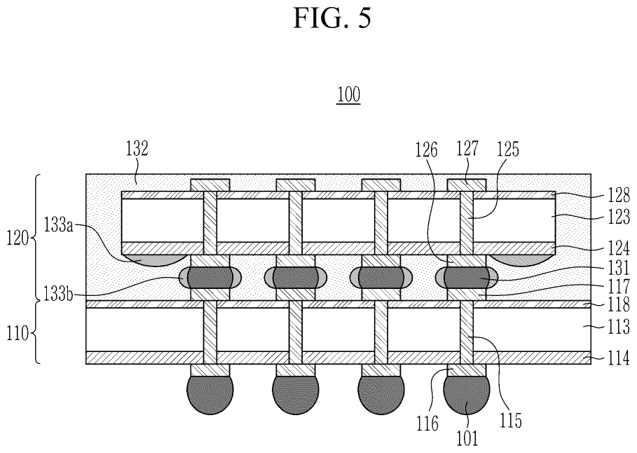

FIG. 5 is a view showing a step of applying the molding material 132 to the buffer die 110 and the memory die 120.

Referring to FIG. 5, the molding material 132 may be applied on the buffer die 110 to cover between the buffer die 110 and the memory die 120 and side and upper surfaces of the memory die 120. The molding material 132 may surround side surfaces of the first insulating member 133a and the second insulating member 133b. The molding material 132 may be in contact with the first insulating member 133a and the second insulating member 133b.

The semiconductor package 100 according to some embodiments may bond the memory die 120 and the buffer die 110 using each of the insulating members 133a and 133b that are thinner than an interval or spacing between the memory die 120 and the buffer die 110. The insulating members 133a and 133b of the semiconductor package 100 according to some embodiments may cover or surround the plurality of first connection members 131 so that a non-conductive film (NCF) fillet area does not occur. The semiconductor package 100 according to some embodiments may significantly improve a defect rate by solving a non-wetting problem that is a bonding defect in a soldering process that may occur when a system in package (SIP) is mounted and a crack issue occurring at an end of the NCF fillet. Therefore, the semiconductor package 100 according to some embodiments may improve a yield of a semiconductor manufacturing process.

Referring to FIGS. 2 to 5, it has been described that the buffer die 110 may be bonded to the memory die 120 in a state in which the plurality of external connection members 101 and the plurality of first connection pads 116 are bonded to a lower surface of the buffer die 110, but the present disclosure is not limited thereto, and after the memory die 120 and the buffer die 110 are bonded, the plurality of first connection pads 116 and the plurality of external connection members 101 may be bonded.

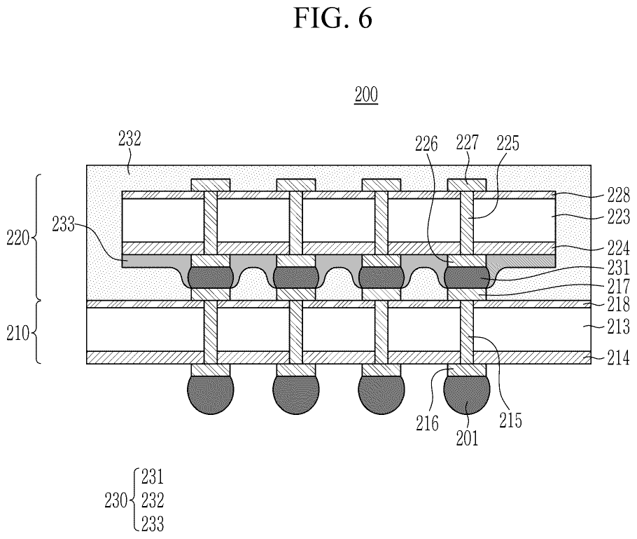

FIG. 6 is a view showing a memory die and a buffer die according to some embodiments.

As shown in FIG. 6, a semiconductor package 200 may include a buffer die (a base logic die or a base die) 210 and a memory die 220.

The buffer die 210 may be disposed at a lowermost portion of the semiconductor package 200. In some embodiments, the buffer die 210 may be disposed between the semiconductor package 200 and an external device.

The buffer die 210 may include a buffer die base or buffer die base substrate 213, a first front side structure (or a first front surface structure) 214, a plurality of first through-hole silicon vias 215, a plurality of first connection pads 216, a plurality of first bonding pads 217, and a first back side structure (or a first back surface structure) 218. Unless otherwise stated, a description of the buffer die 110 of FIG. 1 may be equally applied to that of the buffer die 210.

A plurality of external connection members 201 may be disposed between the plurality of first connection pads 216 and the external device. Each of the plurality of external connection members 201 may electrically connect each of the plurality of first connection pads 216 to the external device. In some embodiments, each of the plurality of external connection members 201 may include a microbump or a solder ball. In some embodiments, each of the plurality of external connection members 201 may include at least one of tin, silver, lead, nickel, copper, and an alloy thereof.

The memory die 220 may include a memory die base or memory die base substrate 223, a second front side structure (or a second front surface structure) 224, a plurality of second through-hole silicon vias 225, a plurality of second connection pads 226, a plurality of second bonding pads 227, and a second back side structure (or a second back surface structure) 228. Unless otherwise stated, a description of the memory die 120 of FIG. 1 may be equally applied to that of the memory die 220.

An interconnection structure 230 may be disposed between the memory die 220 and the buffer die 210. Additionally, the interconnection structure 230 may be disposed to surround the memory die 220. The interconnection structure 230 may include a plurality of first connection members 231, a molding material 232, and an insulating member 233.

Each of the plurality of first connection members 231 may be disposed between each of the plurality of first bonding pads 217 and each of the plurality of second connection pads 226. Each of the plurality of first connection members 231 may electrically connect each of the plurality of second connection pads 226 to a first bonding pad among the plurality of first bonding pads 217 corresponding to each of the plurality of second connection pads 226. In some embodiments, each of the plurality of first connection members 231 may include a microbump. In some embodiments, each of the plurality of first connection members 231 may include at least one of tin, silver, lead, nickel, copper, and an alloy thereof.

In some embodiments, each of the plurality of first connection members 231 may have a height or thickness of 6 μm to 8 μm. For example, each of the plurality of first connection members 231 may have a height of 7.6μm.

The insulating member 233 may be disposed between the buffer die 210 and the memory die 220 adjacent to the buffer die 210. The insulating member 233 may be spaced apart from the buffer die 210. The insulating member 233 may cover or surround at least a portion of a lower surface of the memory die 220 and the plurality of first connection members 231.

In some embodiments, the insulating member 233 may be a polymer tape including an insulating material for uniform adhesion between the buffer die 210 and the memory die 220, bonding of the plurality of first connection members 231 of fine sizes, electrical reliability, structural reliability, and the like. For example, the insulating member 233 may include a non-conductive film (NCF). The insulating member 233 may include at least one of a thermosetting resin, a hardener, a catalyst, a flux, a thermoplastic resin, and an inorganic filler.

In some embodiments, the insulating member 233 may cover or surround the plurality of second connection pads 226, the plurality of first connection members 231, and at least a portion of a lower surface of the second front side structure 224.

The insulating member 233 may surround each of the plurality of first connection members 231. The insulating member 233 may surround side surfaces of the plurality of first connection members 231. The insulating member 233 may be disposed between the plurality of first connection members 231 to prevent an electrical short-circuit from occurring between the plurality of first connection members 231.

The insulating member 233 may be disposed on the lower surface of the memory die 220 (e.g., at least a portion of an area of the second front side structure 224). The insulating member 233 may insulate between the memory die 220 and the buffer die 210. A thickness of the insulating member 233 may be less than an interval or spacing between the memory die 220 and the buffer die 210.

A first portion of the insulating member 233 covering the plurality of first connection members 231 and a second portion of the insulating member 233 covering the lower surface of the second front side structure 224 may be continuously extended (e.g., along the lower surface of the second front side structure and the plurality of first connection members).

The molding material 232 may cover between the buffer die 210 and the memory die 220 on the buffer die 210. The molding material 232 may cover side and upper surfaces of the memory die 220. The molding material 232 may serve to protect and insulate the buffer die 210, the memory die 220, and the plurality of first connection members 231.

In some embodiments, the molding material 232 may be an epoxy molding compound (EMC). In some embodiments, the molding material 232 may include at least one of a thermosetting resin, a hardener, a flame retardant, a catalyst, a release agent, a modifying agent, a colorant, and an inorganic filler. In some embodiments, the inorganic filler of the molding material 232 may include silica.

The molding material 232 may fill an area that is not filled by the insulating member 233 between the memory die 220 and the buffer die 210. The insulating member 233 may be in contact with the molding material 232.

For example, each of the plurality of first connection members 231 may have a height or thickness of 7.6 μm. For example, a thickness of the insulating member 233 may be 2 μm to 3.8 μm. In some embodiments, a thickness of the molding material 232 may be greater than the thickness of the insulating member 233 between the memory die 220 and the buffer die 210.

Because the thickness of the insulating member 233 is small, the insulating member 233 may not overflow in a peripheral direction even if the memory die 220 and the base die 210 are bonded. Accordingly, a fillet area formed by the insulating member 233 may be reduced.

However, the present disclosure is not limited thereto, and the thickness of the insulating member 233 may be a thickness capable of preventing a sweep phenomenon in which the plurality of first connection members 231 flow out or move out of their positions due to thermal compression bonding to escape an electrical path or a short phenomenon in which each of the plurality of first connection members 231 is connected to another first connection member adjacent to each of the plurality of first connection members 231 so that a short circuit occurs.

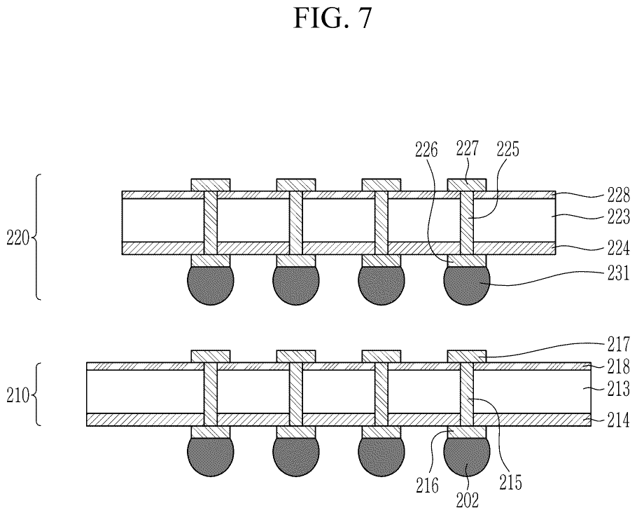

FIGS. 7 to 10 are cross-sectional views for describing a method for manufacturing the memory die and the buffer die according to FIG. 6.

FIG. 7 is a cross-sectional view illustrating a step of aligning the memory die 220 on the buffer die 210.

Referring to FIG. 7, the memory die 220 may be aligned on the buffer die 210. The plurality of first bonding pads 217 may be attached to an upper surface of the buffer die 210 (e.g., on the first back side structure 218). The plurality of second connection pads 226 and the plurality of first connection members 231 may be attached to the lower surface of the memory die 220 (e.g., above or on the second front side structure 224).

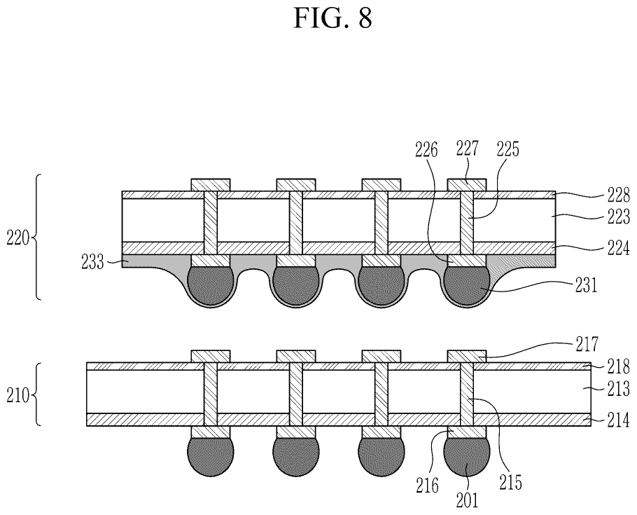

FIG. 8 is a view showing a step of attaching the insulating member 233 on the lower surface of the memory die 220.

Referring to FIG. 8, the insulating member 233 may be attached to the lower surface of the memory die 220 and the plurality of first connection members 231. In some embodiments, the thickness of the insulating member 233 may be less than heights or thicknesses of the plurality of first connection members 231. The plurality of second connection pads 226 and the plurality of first connection members 231 may be covered by the insulating member 233 above or on the lower surface of the memory die 220.

The thickness of the insulating member 233 may be less than an interval or spacing between the memory die 220 and the base die 210. In some embodiments, the thickness of the insulating member 233 may be 2 μm to 3.8 μm.

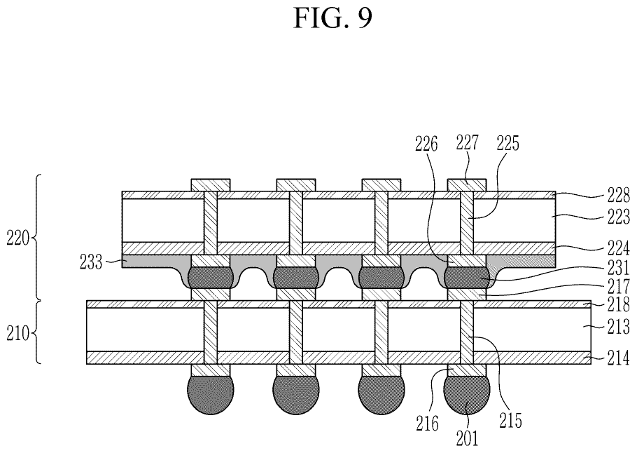

FIG. 9 is a view showing a step of bonding the memory die 220 on the buffer die 210.

Referring to FIG. 9, the memory die 220 may be bonded on the buffer die 210. The memory die 220 may be bonded on the buffer die 210 by a thermal compression process. The plurality of first connection members 231 and an insulating member on the plurality of first connection members 231 may be bonded to a first bonding pad among the plurality of first bonding pads 217 corresponding to the plurality of first connection members 231 and the insulating member on the plurality of first connection members 231 by the thermal compression process.

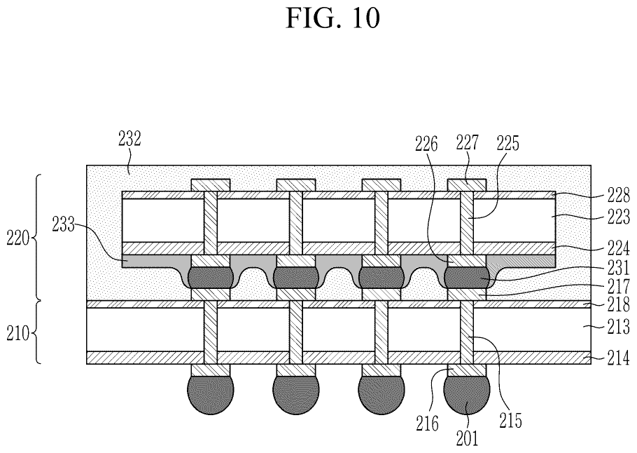

FIG. 10 is a view showing a step of applying the molding material 232 to the buffer die 210 and the memory die 220.

Referring to FIG. 10, the molding material 232 may be applied on the buffer die 210 to cover between the buffer die 210 and the memory die 220 and side and upper surfaces of the memory die 220. The molding material 232 may surround a side surface of the insulating member 233. The molding material 232 may be in contact with the insulating member 233.

The semiconductor package 200 according to some embodiments may bond the memory die 220 and the buffer die 210 using the insulating member 233 thinner than an interval between the memory die 220 and the buffer die 210. The insulating member 233 of the semiconductor package 200 according to some embodiments may cover the plurality of first connection members 231 so that a non-conductive film (NCF) fillet area does not occur. The semiconductor package 200 according to some embodiments may significantly improve a defect rate by solving a wetting problem that is a bonding defect in a soldering process that may occur when a system in package (SIP) is mounted and a crack issue occurring at an end of the NCF fillet. Therefore, the semiconductor package 200 according to some embodiments may improve a yield of a semiconductor manufacturing process.

Referring to FIGS. 7 to 10, it has been described that the buffer die 210 is bonded to the memory die 220 in a state in which the plurality of external connection members 201 and the plurality of first connection pads 216 are bonded to a lower surface of the buffer die 210, but the present disclosure is not limited thereto, and after the memory die 220 and the buffer die 210 are bonded, the plurality of first connection pads 216 and the plurality of external connection members 201 may be bonded.

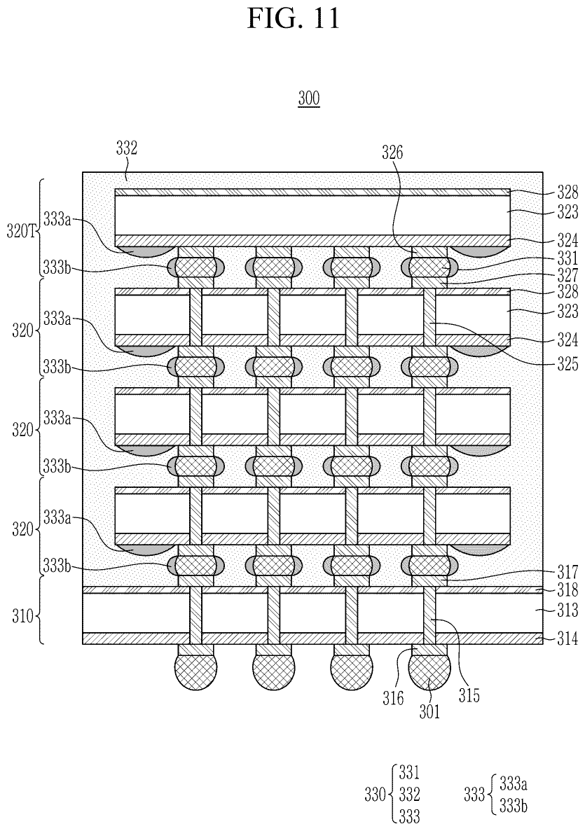

FIG. 11 is a cross-sectional view illustrating a high bandwidth memory according to some embodiments.

Referring to FIG. 11, the high bandwidth memory 300 may include a buffer die (a base logic die or a base die) 310, a semiconductor stack including a plurality of memory dies 320 and 320T and a plurality of interconnection structures 330, and a molding material 332. The high bandwidth memory 300 may be a high performance three-dimensional (3D) stacked dynamic random-access memory (DRAM). The high bandwidth memory 300 may have memory channels through a semiconductor stack manufactured by vertically stacking memory dies to simultaneously implement short latency and high bandwidth compared with a conventional DRAM product, and may reduce a total area occupied by individual DRAMs on a substrate so that it is advantageous for high bandwidth per area and has an advantage of reducing power consumption.

The buffer die 310 may be disposed at a lowermost portion of the high bandwidth memory 300. The buffer die 310 may be disposed between the plurality of memory dies 320 and 320T and an external device.

The buffer die 310 may include a buffer die base or buffer die base substrate 313, a first front side structure (or a first front surface structure) 314, a plurality of first through-hole silicon vias 315, a plurality of first connection pads 316, a plurality of first bonding pads 317, and a first back side structure (or a first back surface structure) 318.

The plurality of memory dies 320 and 320T may be disposed above the buffer die 310.

The plurality of memory dies 320 and 320T may be vertically and sequentially stacked above the buffer die 310. The plurality of memory dies 320 may be stacked on the buffer die 310, and the memory die 320T may be stacked on the plurality of memory dies 320.

A plurality of external connection members 301 may be disposed between the plurality of first connection pads 316 and an external device. Each of the plurality of external connection members 301 may electrically connect each of the plurality of first connection pads 316 to the external device. In some embodiments, each of the plurality of external connection members 301 may include a microbump or a solder ball. In some embodiments, each of the plurality of external connection members 301 may include at least one of tin, silver, lead, nickel, copper, and an alloy thereof.

Each of the plurality of memory dies 320 may include a memory die base or memory die base substrate 323, a second front side structure (or a second front surface structure) 324, a plurality of second through-hole silicon vias 325, a plurality of second connection pads 326, a plurality of second bonding pads 327, and a second back side structure (or a second back surface structure) 328.

The memory die 320T may include a memory die base or memory die base substrate 323, a second front side structure (or a second front surface structure) 324 below the memory die base 323, a second connection pad 326 below the second front side structure 324, and a second back side structure (or a second back surface structure) 328.

In FIG. 11, the high bandwidth memory 300 includes the semiconductor stack in which four memory dies 320 are stacked, but the present disclosure is not limited thereto, and the high bandwidth memory 300 may include a semiconductor stack in which various numbers of memory dies 320 are stacked. For example, the high bandwidth memory 300 may include a semiconductor stack in which 8, 12, 16, or 24 memory dies 320 are stacked.

The interconnection structure 330 may be disposed between the buffer die 310 and a lowermost memory die among the plurality of memory dies 320, or between adjacent memory dies among the plurality of memory dies 320. Additionally, the interconnection structure 330 may be disposed between the memory die 320T and a memory die adjacent to the memory die 320T.

The interconnection structure 330 may include a plurality of first connection members 331, a molding material 332, and an insulating member 333.

Each of the plurality of first connection members 331 may be disposed between each of the plurality of first bonding pads 317 and each of the plurality of second connection pads 326. Each of the plurality of first connection members 331 may electrically connect each of the plurality of second connection pads 326 to a first bonding pad among the plurality of first bonding pads 317 corresponding to each of the plurality of second connection pads 326. In some embodiments, each of the plurality of first connection members 331 may include a microbump. In some embodiments, each of the plurality of first connection members 331 may include at least one of tin, silver, lead, nickel, copper, and an alloy thereof.

In some embodiments, each of the plurality of first connection members 331 may have a height or thickness of 6 μm to 8 μm. For example, each of the plurality of first connection members 331 may have a height of 7.6 μm.

The insulating member 333 may be disposed between the buffer die 310 and a memory die adjacent to the buffer die 310, between adjacent memory dies among the plurality of memory dies 320, and between the memory die 320T and a memory die adjacent to the memory die 320T. The insulating member 333 may be spaced apart from the buffer die 310. The insulating member 333 may cover or surround at least a portion of a lower surface of the memory die 320 and the plurality of first connection members 331.

In some embodiments, the insulating member 333 may be a polymer tape including an insulating material for uniform adhesion between the buffer die 310 and the memory die 320, uniform adhesion between adjacent memory dies, bonding of the plurality of first connection members 331 of fine sizes, electrical reliability, structural reliability, and the like. For example, the insulating member 333 may include a non-conductive film (NCF). The insulating member 333 may include at least one of a thermosetting adhesive resin, a hardener, a catalyst, a flux, a thermoplastic resin, and an inorganic filler.

The insulating member 333 may include a first insulating member 333a and a second insulating member 333b.

The first insulating member 333a may be disposed on lower surfaces of the plurality of memory dies 320 and 320T (e.g., at least a portion of an area of the second front side structure 324). The first insulating member 333a may insulate between the plurality of memory dies 320 and 320T and between the buffer die 310 and a memory die adjacent to the buffer die 310.

The first insulating member 333a may extend in a direction perpendicular to the memory die base 323 from the second front side structure 324 toward the buffer die 310.

The second insulating member 333b may surround each of the plurality of first connection members 331. The second insulating member 333b may surround a side surface of each of the plurality of first connection members 331 except for a surface on which each of the plurality of first connection members 331 is in contact with the second connection pad and the first bonding pad corresponding to each of the plurality of first connection members. The second insulating member 333b may be disposed between the plurality of first connection members 331 to prevent an electrical short-circuit from occurring between the plurality of first connection members 331.

The second insulating member 333b may extend from the plurality of first connection members 331 in a direction parallel to the memory die base 323 or the buffer die base 313. For example, the second insulating member 333b may extend outwardly from a center of each of the plurality of first connection members 331 in the direction parallel to the buffer die base 313.

A thickness of each of the first insulating member 333a and the second insulating member 333b may be less than an interval or spacing between the buffer die 310 and a memory die adjacent to the buffer die 310 and an interval between the plurality of memory dies 320 and 320T. In some embodiments, the thickness of each of the first insulating member 333a and the second insulating member 333b may be less than heights or thicknesses of the plurality of first connection members 331. The second insulating member 333b may be disposed to be separated or spaced apart from the first insulating member 333a.

The molding material 332 may be or cover between the buffer die 310 and a memory die adjacent to the buffer die 310 on the buffer die 310. The molding material 332 may cover or be on side and upper surfaces of each of the plurality of memory dies 320 and 320T. The molding material 332 may serve to protect and insulate the buffer die 310, the plurality of memory dies 320 and 320T, and the plurality of first connection members 331.

In some embodiments, the molding material 332 may be an epoxy molding compound (EMC). In some embodiments, the molding material 332 may include at least one of a thermosetting resin, a hardener, a flame retardant, a catalyst, a release agent, a modifying agent, a colorant, and an inorganic filler. In some embodiments, the inorganic filler of the molding material 332 may include silica.

In some embodiments, the molding material 332 may fill an area that is not filled by the first insulating member 333a and the second insulating member 333b. The first insulating member 333a and the second insulating member 333b may be in contact with the molding material 332.

For example, each of the plurality of first connection members 331 may have a height or thickness of 7.6 μm. For example, a thickness of each of the first insulating member 333a and the second insulating member 333b may be 2 μm to 3.8 μm. In some embodiments, a thickness of the molding material 332 may be greater than the thickness of each of the first insulating member 333a and the second insulating member 333b between the buffer die 310 and a memory die adjacent to the buffer die 310 and between adjacent memory dies among the plurality of memory dies 320 and 320T.

Because the thickness of each of the first insulating member 333a and the second insulating member 333b is small, the first insulating member 333a and the second insulating member 333b may not overflow in a peripheral direction even if the memory die 320 and the buffer die 310 are bonded. Accordingly, a fillet area formed by the insulating member 333 may be reduced.

However, the present disclosure is not limited thereto, and the thickness of each of the first insulating member 333a and the second insulating member 333b may be a thickness capable of preventing a sweep phenomenon in which the plurality of first connection members 331 flow out or move out of their positions due to thermal compression bonding to escape an electrical path or a short phenomenon in which each of the plurality of first connection members 331 is connected to another first connection member adjacent to each of the plurality of first connection members 331 so that a short circuit occurs.

The high bandwidth memory 300 according to some embodiments may bond the memory die 320 and the buffer die 310 using each of the insulating members 333a and 333b that are thinner than an interval or spacing between the memory die 320 and the buffer die 310. The insulating members 333a and 333b of the high bandwidth memory 300 according to some embodiments may cover the plurality of first connection members 331 so that a non-conductive film (NCF) fillet area does not occur. The high bandwidth memory 300 according to some embodiments may significantly improve a defect rate by solving a wetting problem that is a bonding defect in a soldering process that may occur when a system in package (SIP) is mounted and a crack issue occurring at an end of the NCF fillet. Therefore, the high bandwidth memory 300 according to some embodiments may improve a yield of a semiconductor manufacturing process.

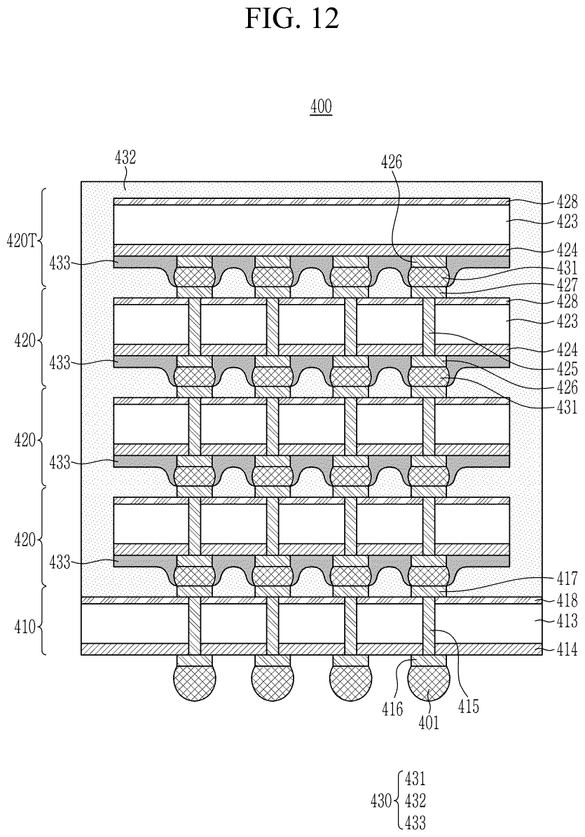

FIG. 12 is a cross-sectional view illustrating a high bandwidth memory according to some other embodiments.

Referring to FIG. 12, the high bandwidth memory 400 may include a buffer die (a base logic die or a base die) 410, a semiconductor stack including a plurality of memory dies 420 and 420T and a plurality of interconnection structures 430, and a molding material 432.

The buffer die 410 may be disposed at a lowermost portion of the high bandwidth memory 400. The buffer die 410 may be disposed between the plurality of memory dies 420 and 420T and an external device.

The buffer die 410 may include a buffer die base or buffer die base substrate 413, a first front side structure (or a first front surface structure) 414, a plurality of first through-hole silicon vias 415, a plurality of first connection pads 416, a plurality of first bonding pads 417, and a first back side structure (or a first back surface structure) 418. Unless otherwise stated, a description of the buffer die 310 of FIG. 11 may be equally applied to that of the buffer die 410.

The plurality of memory dies 420 and 420T may be disposed above the buffer die 410.

The plurality of memory dies 420 and 420T may be vertically and sequentially stacked above the buffer die 410. The plurality of memory dies 420 may be stacked on the buffer die 410, and the memory die 420T may be stacked on the plurality of memory dies 420.

A plurality of external connection members 401 may be disposed between the plurality of first connection pads 416 and an external device. Each of the plurality of external connection members 401 may electrically connect each of the plurality of first connection pads 416 to the external device. In some embodiments, each of the plurality of external connection members 401 may include a microbump or a solder ball. In some embodiments, each of the plurality of external connection members 401 may include at least one of tin, silver, lead, nickel, copper, and an alloy thereof.

Each of the plurality of memory dies 420 may include a memory die base or memory die base substrate 423, a second front side structure (or a second front surface structure) 424, a plurality of second through-hole silicon vias 425, a plurality of second connection pads 426, a plurality of second bonding pads 427, and a second back side structure (or a second back surface structure) 428. Unless otherwise stated, a description of the memory die 320 of FIG. 11 may be equally applied to that of the memory die 420.

The memory die 420T may include a memory die base or memory die base substrate 423, a second front side structure (or a second front surface structure) 424 below the memory die base 423, a second connection pad 426 below the second front side structure 424, and a second back side structure (or a second back surface structure) 428.

In FIG. 12, the high bandwidth memory 400 includes the semiconductor stack in which four memory dies 420 are stacked, but the present disclosure is not limited thereto, and the high bandwidth memory 400 may include a semiconductor stack in which various numbers of memory dies 420 are stacked. For example, the high bandwidth memory 400 may include a semiconductor stack in which 8, 12, 16, or 24 memory dies 420 are stacked.

The interconnection structure 430 may be disposed between the buffer die 410 and a lowermost memory die among the plurality of memory dies 420. Additionally, the interconnection structure 430 may be disposed between adjacent memory dies among the plurality of memory dies 420. The interconnection structure 430 may be disposed between the memory die 420T and a memory die adjacent to the memory die 420T.

The interconnection structure 430 may include a plurality of first connection members 431, a molding material 432, and an insulating member 433.

Each of the plurality of first connection members 431 may be disposed between each of the plurality of first bonding pads 417 and each of the plurality of second connection pads 426. Each of the plurality of first connection members 431 may electrically connect each of the plurality of second connection pads 426 to a first bonding pad among the plurality of first bonding pads 417 corresponding to each of the plurality of second connection pads 426. In some embodiments, each of the plurality of first connection members 431 may include a microbump. In some embodiments, each of the plurality of first connection members 431 may include at least one of tin, silver, lead, nickel, copper, and an alloy thereof.

In some embodiments, each of the plurality of first connection members 431 may have a height or thickness of 6 μm to 8 μm. For example, each of the plurality of first connection members 431 may have a height of 7.6 μm.

The insulating member 433 may be disposed between the buffer die 410 and a memory die adjacent to the buffer die 410, between adjacent memory dies among the plurality of memory dies 420, and between the memory die 420T and a memory die adjacent to the memory die 420T. The insulating member 433 may be spaced apart from the buffer die 410. The insulating member 433 may cover or surround at least a portion of a lower surface of the memory die 420 and the plurality of first connection members 431.

In some embodiments, the insulating member 433 may be a polymer tape including an insulating material for uniform adhesion between the buffer die 410 and the memory die 420, uniform adhesion between adjacent memory dies, bonding of the plurality of first connection members 431 of fine sizes, electrical reliability, structural reliability, and the like. For example, the insulating member 433 may include a non-conductive film (NCF). The insulating member 433 may include at least one of a thermosetting resin, a hardener, a catalyst, a flux, a thermoplastic resin, and an inorganic filler.

In some embodiments, the insulating member 433 may surround the plurality of second connection pads 426, the plurality of first connection members 431, and at least a portion of a lower surface of the second front side structure 424.

The insulating member 433 may surround each of the plurality of first connection members 431. The insulating member 433 may surround side surfaces of the plurality of first connection members 431. The insulating member 433 may be disposed between the plurality of first connection members 431 to prevent an electrical short-circuit from occurring between the plurality of first connection members 431.

The insulating member 433 may be disposed on lower surfaces of the memory dies 420 and 420T (e.g., at least a portion of the second front side structure 424). The insulating member 433 may insulate between the buffer die 410 and a memory die adjacent to the buffer die 410 and between adjacent memory dies among the plurality of memory dies 420 and 420T. A thickness of the insulating member 433 may be less than an interval or spacing between the plurality of memory dies 420 and 420T and an interval or spacing between the buffer die 410 and a memory die adjacent to the buffer die 410.

A first portion of the insulating member 433 covering the plurality of first connection members 431 and a second portion of the insulating member 433 covering the lower surfaces of the memory dies 420 and 420T (e.g., a second front side structure 424) may be continuously extended (e.g., along the lower surface of the memory die and the plurality of first connection members).

The molding material 432 may be or cover between the buffer die 410 and a memory die adjacent to the buffer die 410 on the buffer die 410. The molding material 432 may be on or cover side and upper surfaces of each of the plurality of memory dies 420 and 420T. The molding material 432 may serve to protect and insulate the buffer die 410, the plurality of memory dies 420 and 420T, and the plurality of first connection members 431.

In some embodiments, the molding material 432 may be an epoxy molding compound (EMC). In some embodiments, the molding material 432 may include at least one of a thermosetting resin, a hardener, a flame retardant, a catalyst, a release agent, a modifying agent, a colorant, and an inorganic filler. In some embodiments, the inorganic filler of the molding material 432 may include silica.

The molding material 432 may fill an area that is not filled by the insulating member 433 between the memory die 420 and the buffer die 410 and between adjacent memory dies among the plurality of memory dies 420 and 420T. The insulating member 433 may be in contact with the molding material 432.

For example, each of the plurality of first connection members 431 may have a height or thickness of 7.6 μm. For example, a thickness of the insulating member 433 may be 2 μm to 3.8 μm. In some embodiments, a thickness of the molding material 432 may be greater than the thickness of the insulating member 433 between the buffer die 410 and a memory die adjacent to the buffer die 410 and between adjacent memory dies among the plurality of memory dies 420 and 420T.

Because the thickness of the insulating member 433 is small, the insulating member 433 may not overflow in a peripheral direction even if the plurality of memory dies 420 and the buffer die 410 are bonded. Accordingly, a fillet area formed by the insulating member 433 may be reduced.

However, the present disclosure is not limited thereto, and the thickness of the insulating member 433 may be a thickness capable of preventing a sweep phenomenon in which the plurality of first connection members 431 flow out or move out of their positions due to thermal compression bonding to escape an electrical path or a short phenomenon in which each of the plurality of first connection members 431 is connected to another first connection member adjacent to each of the plurality of first connection members 431 so that a short circuit occurs.

The high bandwidth memory 400 according to some embodiments may bond the memory die 420 and the buffer die 410 using the insulating member 433 that is thinner than an interval or spacing between the memory die 420 and the buffer die 410. The insulating member 433 of the high bandwidth memory 400 according to some embodiments may cover the plurality of first connection members 431 so that a non-conductive film (NCF) fillet area does not occur. The high bandwidth memory 400 according to some embodiments may significantly improve a defect rate by solving a wetting problem that is a bonding defect in a soldering process that may occur when a system in package (SIP) is mounted and a crack issue occurring at an end of the NCF fillet. Therefore, the high bandwidth memory 400 according to some embodiments may improve a yield of a semiconductor manufacturing process.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a first semiconductor die;
a plurality of first connection members on the first semiconductor die;
a second semiconductor die on the plurality of first connection members;
an insulating member spaced apart from the first semiconductor die between the first semiconductor die and the second semiconductor die and that covers at least a portion of a lower surface of the second semiconductor die and the plurality of first connection members; and
a molding material that covers at least a portion of the second semiconductor die and is between the first semiconductor die and the second semiconductor die.

2. The semiconductor package of claim 1, wherein the molding material covers upper and side surfaces of the second semiconductor die.

3. The semiconductor package of claim 1, wherein the insulating member covers side surfaces of the plurality of first connection members, and the insulating member is in contact with the molding material.

4. The semiconductor package of claim 1, wherein the insulating member has a thickness less than an interval between the first semiconductor die and the second semiconductor die.

5. The semiconductor package of claim 4, wherein each of the plurality of first connection members has a height of 6 μm to 8 μm, and the insulating member has a thickness of 2 μm to 3.8 μm.

6. The semiconductor package of claim 1, wherein the insulating member includes a first portion surrounding the plurality of first connection members and a second portion in contact with the lower surface of the second semiconductor die, and the first portion and the second portion are spaced apart from one another.

7. The semiconductor package of claim 1, wherein the insulating member includes a first portion surrounding the plurality of first connection members and a second portion in contact with the lower surface of the second semiconductor die, and the first portion and the second portion continuously extend along the lower surface of the second semiconductor die and the plurality of first connection members.

8. The semiconductor package of claim 1, wherein the molding material includes an epoxy molding compound (EMC).

9. The semiconductor package of claim 1, wherein the insulating member includes a non-conductive film (NCF).

10. A high bandwidth memory comprising:
a buffer die;
a plurality of memory dies stacked in a vertical direction on the buffer die;
a plurality of first connection members between the buffer die and the memory die adjacent the buffer die and between memory dies adjacent each other among the plurality of memory dies;
a plurality of insulating members between the buffer die and the memory die adjacent the buffer die and between memory dies adjacent each other among the plurality of memory dies and surrounding the plurality of first connection members; and
a molding material on the buffer die and covering the plurality of insulating members, between the buffer die and the memory die adjacent the buffer die, between adjacent memory dies among the plurality of memory dies, and at least partially covering the plurality of memory dies.

11. The high bandwidth memory of claim 10, wherein a thickness of each of the plurality of insulating members is less than an interval between the buffer die and the memory die adjacent the buffer die, and is less than an interval between the memory dies adjacent each other among the plurality of memory dies.

12. The high bandwidth memory of claim 10, wherein the molding material covers upper and side surfaces of the plurality of memory dies.

13. The high bandwidth memory of claim 10, wherein each of the plurality of insulating members surrounds side surfaces of the plurality of first connection members and is in contact with the molding material.

14. The high bandwidth memory of claim 10, wherein each of the plurality of first connection members has a height of 6 μm to 8 μm, and each of the plurality of insulating members has a thickness of 2 μm to 3.8 μm.

15. The high bandwidth memory of claim 10, wherein each of the plurality of insulating members includes a first portion surrounding the plurality of first connection members and a second portion in contact with a lower surface of a memory die among the plurality of memory dies corresponding thereto, and the first portion and the second portion are spaced apart from each other.

16. The high bandwidth memory of claim 10, wherein each of the plurality of insulating members includes a first portion covering the plurality of first connection members and a second portion in contact with a lower surface of a memory die among the plurality of memory dies corresponding thereto, and the first portion and the second portion continuously extend along the lower surface of a memory die and the plurality of first connection members.

17. The high bandwidth memory of claim 10, wherein the molding material includes an epoxy molding compound (EMC).

18. The high bandwidth memory of claim 10, wherein each of the plurality of insulating members includes a non-conductive film (NCF).

19. A method for manufacturing a semiconductor package, comprising:
forming a plurality of first bonding pads on a first semiconductor die;
forming a plurality of first connection members on a lower surface of a second semiconductor die;
attaching an insulating member on the lower surface of the second semiconductor die and on the plurality of first connection members, wherein the insulating member has a thickness less than heights of the plurality of first connection members;
bonding the second semiconductor die on the first semiconductor die; and
molding the first semiconductor die and the second semiconductor die on the first semiconductor die.

20. The method of claim 19, wherein molding the first semiconductor die and the second semiconductor die on the first semiconductor die comprises:
molding between the first semiconductor die and the second semiconductor die; and
molding an upper surface and a side surface of the second semiconductor die.
